(19) United States
(12) Patent Application Publication
(10) Pub. No.: US 2026/0351174 A1
(43) Pub. Date: Nov. 5, 2026

(54) PIXEL AND ELECTRONIC DEVICE

(71) Applicant: Samsung Display Co., Ltd., Yongin-si (KR)

(72) Inventors: Minki YANG, Yongin-si (KR); Daehyun KIM, Yongin-si (KR); Mihae KIM, Yongin-si (KR); Heyjin SHIN, Yongin-si (KR); Huigyeong YUN, Yongin-si (KR); Hwansoo JANG, Yongin-si (KR); Keukjin JEONG, Yongin-si (KR)

(73) Assignee: Samsung Display Co., Ltd., Yongin-si (KR)

(21) Appl. No.: 19/539,817

(22) Filed: Feb. 13, 2026

(30) Foreign Application Priority Data
Mar. 11, 2025 (KR) 10-2025-0031483

(51) Int. Cl. G09G 3/3233

(52) U.S. Cl. CPC G09G 3/3233; G09G 2300/0819; G09G 2300/0852; G09G 2300/0861; G09G 2310/0286; G09G 2310/08

(57) ABSTRACT

According to one or more embodiments, a pixel includes a first transistor including a first terminal connected to a first voltage line, a second transistor including a first terminal connected to a data line, a third transistor connected to a gate and a second terminal of the first transistor, a fourth transistor connected to the gate of the first transistor and a second voltage line, a fifth transistor connected to a second terminal of the second transistor and a third voltage line, a sixth transistor connected to the second terminal of the first transistor and a light-emitting diode, a seventh transistor connected to the light-emitting diode and a fourth voltage line, a first capacitor connected to the first voltage line and the second transistor, and a second capacitor connected to the second terminal of the second transistor and the gate of the first transistor.

### CROSS-REFERENCE TO RELATED APPLICATION

This application is based on and claims priority under 35 U.S.C. § 119 to Korean Patent Application No. 10-2025-0031483, filed on Mar. 11, 2025, in the Korean Intellectual Property Office, the disclosure of which is incorporated by reference herein in its entirety.

### BACKGROUND

### 1. Field

One or more embodiments relate to a pixel, a display device, and an electronic device including the same.

### 2. Description of the Related Art

Recently, display devices have been widely used. For example, because the thickness and weight of the display devices have been decreased, the range of use for display devices has widened.

As the uses of the display devices have been diversified, there may be various methods for designing the shapes of the display devices. Also, as the uses of the display devices have been diversified, the number of functions that may be integrated with and/or connected to the display devices has also increased.

### SUMMARY

One or more embodiments include a high-resolution display device. However, this is merely an example, and the scope of the present disclosure is not limited thereto.

Additional aspects will be set forth in part in the description which follows and, in part, will be apparent from the description, or may be learned by practice of the presented embodiments of the disclosure.

According to one or more embodiments, a pixel includes a first transistor including a first terminal connected to a first voltage line, a second transistor including a first terminal connected to a data line, a third transistor connected to a gate and a second terminal of the first transistor, a fourth transistor connected to the gate of the first transistor and a second voltage line, a fifth transistor connected to a second terminal of the second transistor and a third voltage line, a sixth transistor connected to the second terminal of the first transistor and a light-emitting diode, a seventh transistor connected to the light-emitting diode and a fourth voltage line, a first capacitor connected to the first voltage line and the second transistor, and a second capacitor connected to the second terminal of the second transistor and the gate of the first transistor. A gate of the second transistor, a gate of the third transistor, a gate of the fifth transistor, and a gate of the seventh transistor are connected to a first gate line. Each of the second transistor, the third transistor, and the seventh transistor have a same channel type as the first transistor. A channel type of the fifth transistor is opposite to the channel type of the first transistor.

In at least one example embodiment, a gate of the fourth transistor may be connected to a second gate line, the first gate line may be configured to receive a first gate signal, the second gate line may be configured to receive a second gate signal, and the second gate signal provided to the second gate line may have the same waveform as the first gate signal provided to the first gate line and may be shifted forward in time relative to the first gate signal.

In at least one example embodiment, channel types of the fourth transistor and the sixth transistor may be the same as the channel type of the first transistor.

In at least one example embodiment, the pixel may be configured such that the second transistor is turned off by a first-level voltage of the first gate signal and turned on by a second-level voltage of the first gate signal, the fourth transistor is turned off by a first-level voltage of the second gate signal and turned on by a second-level voltage of the second gate signal, the fifth transistor is turned on by the first-level voltage of the first gate signal and turned off by the second-level voltage of the first gate signal, the sixth transistor is turned off by a first-level voltage of a third gate signal and turned on by a second level of the third gate signal, the third gate signal provided to a gate of the sixth transistor, and such that during a first period of a frame a voltage at the second terminal of the second transistor is a reference voltage provided to the third voltage line, and a voltage at the gate of the first transistor is a first initialization voltage provided to the second voltage line. During the first period of the frame, the second transistor may be off, the fifth transistor may be on, the fourth transistor may be on, and the sixth transistor may be off.

In at least one example embodiment, the pixel may be configured such that, during a second period after the first period of the frame, the voltage at the second terminal of the second transistor corresponds to a data signal provided to the data line, and the voltage at the gate of the first transistor corresponds to a difference between a driving voltage provided to the first voltage line and a threshold voltage of the first transistor. During the second period, the second transistor may be on, the fifth transistor may be off, the fourth transistor may be off, and the sixth transistor may be off.

In at least one example embodiment, the pixel may be configured such that, during a third period after the second period of the frame, the voltage at the second terminal of the second transistor is the reference voltage, and the voltage at the gate of the first transistor is changed by an amount corresponding to a voltage variation at the second terminal of the second transistor. During the third period, second transistor may be off, the fifth transistor may be on, the fourth transistor may be off, and the sixth transistor is off.

In at least one example embodiment the pixel may be configured such that, during an emission period after the third period of the frame, the second transistor is off, the fifth transistor is on, the fourth transistor is off, and the sixth transistor is on.

According to one or more embodiments, a pixel includes a first transistor including a first terminal connected to a first voltage line, a second transistor including a first terminal connected to a data line, a third transistor connected to a gate and a second terminal of the first transistor, a fourth transistor connected to the gate of the first transistor and a second voltage line, a fifth transistor connected to a second terminal of the second transistor and a third voltage line, a sixth transistor connected to the second terminal of the first transistor and a light-emitting diode, a seventh transistor connected to the light-emitting diode and a fourth voltage line, a first capacitor connected to the first voltage line and the second transistor, and a second capacitor connected to the second terminal of the second transistor and the gate of the first transistor. A gate of the second transistor, a gate of the third transistor, a gate of the fifth transistor, and a gate of the seventh transistor are connected to a first gate line. Channel types of the second transistor, the third transistor, and the seventh transistor are opposite to a channel type of the first transistor; and the fifth transistor has a same channel type as the first transistor.

In at least one example embodiment, a gate of the fourth transistor may be connected to a second gate line, the first gate line may be configured to receive a first gate signal, the second gate line is configured to receive a second gate signal, and the second gate signal provided to the second gate line may have a same waveform as the first gate signal provided to the first gate line and may be shifted forward in time relative to the first gate signal.

In at least one example embodiment, a channel type of the fourth transistor may be opposite to the channel type of the first transistor, and a channel type of the sixth transistor may be the same as the channel type of the first transistor.

In at least one example embodiment, the pixel may be configured such that the fourth transistor is turned on by a first-level voltage of the second gate signal and turned off by a second-level voltage of the second gate signal, the second transistor is turned on by a first-level voltage of the first gate signal and turned off by a second-level voltage of the first gate signal, the fifth transistor is turned off by the first-level voltage of the first gate signal and turned on by the second-level voltage of the first gate signal, the sixth transistor is turned off by a first-level voltage of a third gate signal and turned on by a second-level voltage of the third gate signal, and such that, during a first period of a frame, a voltage at the second terminal of the second transistor is a reference voltage provided to the third voltage line, and a voltage at the gate of the first transistor is a first initialization voltage provided to the second voltage line. During first period of the frame the second transistor may be off, the fourth transistor may be on, the fifth transistor may be on, and the sixth transistor may be off.

In at least one example embodiment, the pixel may be configured such that, during a second period after the first period of the frame, the voltage at the second terminal of the second transistor corresponds to a data signal provided to the data line, and the voltage at the gate of the first transistor corresponds to a difference between a driving voltage provided to the first voltage line and a threshold voltage of the first transistor. During the second period the second transistor may be on, the fifth transistor may be off, the fourth transistor may be off, and the sixth transistor may be off.

In at least one example embodiment, the pixel may be configured such that, during a third period after the second period of the frame, the voltage at the second terminal of the second transistor may be the reference voltage, and the voltage at the gate of the first transistor may be changed from a voltage in the second period by an amount corresponding to a voltage variation at the second terminal of the second transistor. During the third period the second transistor may be off, the fifth transistor may be on, the fourth transistor may be off, and the sixth transistor may be off.

In at least one example embodiment, the pixel may be configured such that, during an emission period after the third period of the frame, the second transistor is off and the fifth transistor is on, the fourth transistor is off, and the sixth transistor is on.

In at least one example embodiment, channel types of the fourth transistor and the sixth transistor may be opposite to the channel type of the first transistor.

In at least one example embodiment, the pixel may be configured such that the fourth transistor is turned on by a first-level voltage of the second gate signal and turned off by a second-level voltage of the second gate signal, the second transistor is turned on by a first-level voltage of the first gate signal and turned off by a second-level voltage of the first gate signal, the fifth transistor is turned off by the first-level voltage of the first gate signal and turned on by the second-level voltage of the first gate signal, the sixth transistor is turned on by a first-level voltage of a third gate signal and turned off by a second-level voltage of the third gate signal, and such that, during a first period of a frame, a voltage at the second terminal of the second transistor is a reference voltage provided to the third voltage line, and a voltage at the gate of the first transistor is a first initialization voltage provided to the second voltage line. During the first period of the frame, the fourth transistor may be turned on, the second transistor may be off, the fifth transistor may be on, and the sixth transistor may be off.

In at least one example embodiment, the pixel may be configured such that, during a second period after the first period of the frame, the voltage at the second terminal of the second transistor may correspond to a data signal provided to the data line, and the voltage at the gate of the first transistor may correspond to a difference between a driving voltage provided to the first voltage line and a threshold voltage of the first transistor. During the second period, the second transistor may be on, the fifth transistor may be off, the fourth transistor may be off, and the sixth transistor may be off.

In at least one example embodiment, the pixel may be configured such that, during a third period after the second period of the frame, the voltage at the second terminal of the second transistor may be the reference voltage, and the voltage at the gate of the first transistor may be a voltage that is changed from a voltage in the second period by an amount corresponding to a voltage variation at the second terminal of the second transistor. During the third period the second transistor may be off, the fifth transistor may be on, the fourth transistor may be off, and the sixth transistor may be off.

In at least one example embodiment, the pixel may be configured such that, during an emission period after the third period of the frame, the second transistor is off and the fifth transistor is on, the fourth transistor is off, and the sixth transistor is on.

According to one or more embodiments, an electronic device includes a controller configured to receive an on-operation signal from a processor and, based on the on-operation signal, output a control signal, a gate driving circuit configured to receive the control signal and sequentially output at least one gate signal, and a display panel in which a plurality of pixels are arranged, the plurality of pixels configured to receive the at least one gate signal. Each of the plurality of pixels includes a first transistor including a first terminal connected to a first voltage line, a second transistor including a first terminal connected to a data line, a third transistor connected to a gate and a second terminal of the first transistor, a fourth transistor connected to the gate of the first transistor and a second voltage line, a fifth transistor connected to a second terminal of the second transistor and a third voltage line, a sixth transistor connected to the second terminal of the first transistor and a light-emitting diode, a seventh transistor connected to the light-emitting diode and a fourth voltage line, a first capacitor connected to the first voltage line and the second transistor, and a second capacitor connected to the second terminal of the second transistor and the gate of the first transistor. A gate of the second transistor, a gate of the third transistor, a gate of the fifth transistor, and a gate of the seventh transistor are connected to a first gate line. A channel type of the fifth transistor is the same as or opposite to a channel type of the first transistor. A channel type of the fifth transistor is opposite to the channel types of the second transistor and the third transistor.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are schematic diagrams of a display device according to at least one example embodiment;

FIG. 2 is a schematic diagram of a display device according to at least one example embodiment;

FIG. 3 is a schematic diagram of a portion of a gate driving circuit of FIG. 2;

FIG. 4 is a schematic equivalent circuit diagram of a pixel according to at least one example embodiment;

FIG. 5 is a timing diagram showing an operation of the pixel of FIG. 4, according to at least one example embodiment;

FIG. 6 is a schematic equivalent circuit diagram of a pixel according to at least one example embodiment;

FIG. 7 is a timing diagram showing an operation of the pixel of FIG. 6;

FIG. 8 is a schematic equivalent circuit diagram of a pixel according to at least one example embodiment;

FIG. 9 is a timing diagram showing an operation of the pixel of FIG. 8;

FIGS. 10 to 12 respectively are schematic equivalent circuit diagrams of a pixel according to at least one example embodiment;

FIG. 13 is a block diagram of an electronic device according to at least one example embodiment; and

FIG. 14 shows schematic diagrams of electronic devices according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, an expression such as “A and/or B” indicates A, B, or A and B. Also, an expression such as “at least one of A and B” indicates A, B, or A and B. For example, the expression “at least one of a, b, or c” indicates only a; only b; only c; both a and b; both a and c; both b and c; all of a, b, and c; and/or variations thereof.

As the disclosure allows for various changes and numerous embodiments, particular embodiments will be shown in the drawings and described in detail in the written description. The attached drawings for illustrating embodiments of the disclosure are referred to in order to gain a sufficient understanding of the present disclosure, the merits thereof, and the objectives accomplished by the implementation of the disclosure. The disclosure may, however, be embodied in many different forms and should not be construed as being limited to the embodiments set forth herein.

It will be understood that although the terms “first,” “second,” etc., may be used herein to describe various elements, these elements should not be limited by these terms, and these elements are only used to distinguish one element from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or elements, but do not preclude the presence or addition of one or more other features or elements.

It will be understood that when X is referred to as being connected to Y, X may be electrically, functionally, or physically connected to Y. Here, X and Y may each be an object (e.g., an apparatus, a device, a circuit, a wire, an electrode, a terminal, a conductive layer, a layer, or the like). Therefore, a connection relationship between X and Y is not limited to a certain connection relationship, e.g., a connection relationship illustrated in the drawings or stated in the detailed description, and may include relationships other than the connection relationship in the drawings or detailed description. Moreover, terms like “processor,” “module,” etc., which refer to a functional element configured to process at least one function or operation, may be implemented by processing circuitry, such as a hardware, a software, or a combination thereof. For example, unless expressly indicated otherwise, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

For example, the case where X is electrically connected to Y may include a case, where X is in direct contact with and electrically connected to Y, and a case, where one or more elements (e.g., a switch, a transistor, a capacitive element, an inductor, a resistor, a diode, etc.) are connected between X and Y to enable the electrical connection between X and Y.

In embodiments below, the term “on” used in relation to a device state may indicate an active state of a device, and the term “off” may indicate an inactive state of the device. The term “on” used in relation to a signal received by a device may refer to a signal for activating the device, and the term “off” may refer to a signal for deactivating the device. The device may be activated according to a high-level voltage or low-level voltage. For example, a P-channel transistor (a P-type transistor) is activated by a low-level voltage, and an N-channel transistor (an N-type transistor) is activated by a high-level voltage. Therefore, it should be understood that “on” voltages applied to the P-type transistor and the N-type transistor have opposite voltage levels (low vs. high).

In embodiments below, the x direction, y direction, and z direction are not limited to directions following three axes on the rectangular coordinate system and may be interpreted in a broader sense. For example, the x direction, y direction, and z direction may be orthogonal to each other, but may refer to different directions that are not orthogonal to each other. Additionally, it will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly; and the term “upper portion” or “on” may also include “to be present above, below, in the left and right sides on a non-contact basis” as well as “to be on the top, bottom, left, and right portions in directly contact with”.

Sizes of elements in the drawings may be exaggerated for convenience of explanation. In other words, since sizes and thicknesses of elements in the drawings are arbitrarily illustrated for convenience of explanation, the following embodiments are not limited thereto.

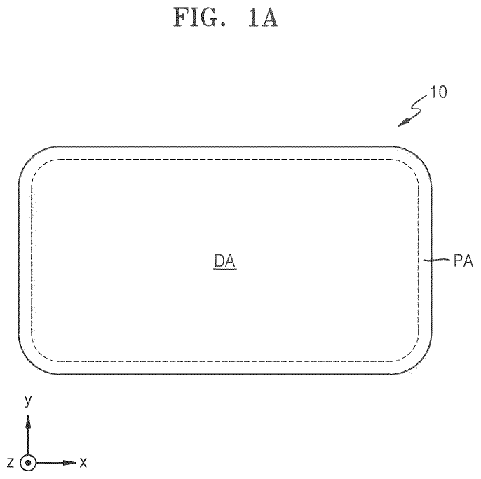

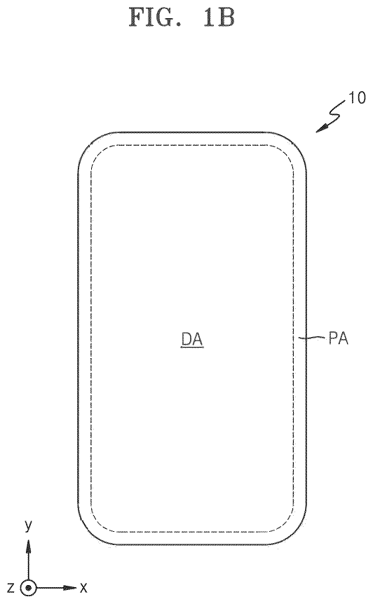

FIGS. 1A and 1B are schematic diagrams of a display device according to at least one example embodiment.

Referring to FIGS. 1A and 1B, a display device 10 may include a display area DA, where images are displayed, and a peripheral area PA outside the display area DA. The display area DA may be entirely surrounded by the peripheral area PA.

In a plan view, the display area DA may have a rectangular shape (e.g., having four sides). In other example embodiments, the display area DA may have a polygonal shape, such as a triangle, a pentagon, or a hexagon, a circular shape, an oval shape, or the like. The display area DA may have a shape with rounded corners. In at least one example embodiment, as shown in FIG. 1A, the display device 10 may have a display area DA having a shape in which the length in the x direction is greater than that in the y direction. In at least one example embodiment, as shown in FIG. 1B, the display device 10 may have a display area DA having a shape in which the length in the y direction greater than that in the x direction. In at least one example embodiment, the display device 10 of FIG. 1A may be in a landscape orientation; and the display device 10 of FIG. 1B may be in a portrait orientation. In at least some example embodiments, the display device 10 may be configured to switch between the landscape and portrait orientations.

The display device 10 may display moving images or still images and may provide visual information to a user. The display device 10 according to at least one example embodiment may be a display device, such as an organic light-emitting display device, an inorganic light-emitting display device (or an inorganic EL display device), a quantum dot (QD) light-emitting display device.

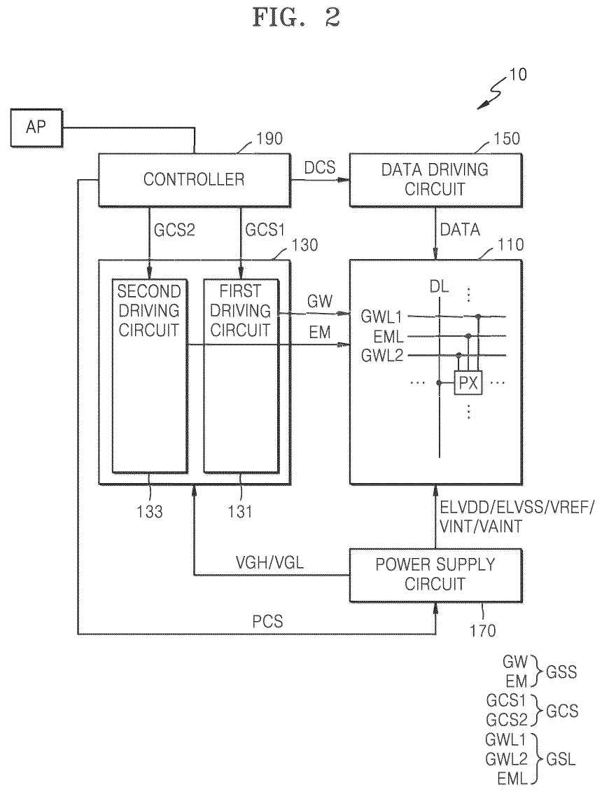

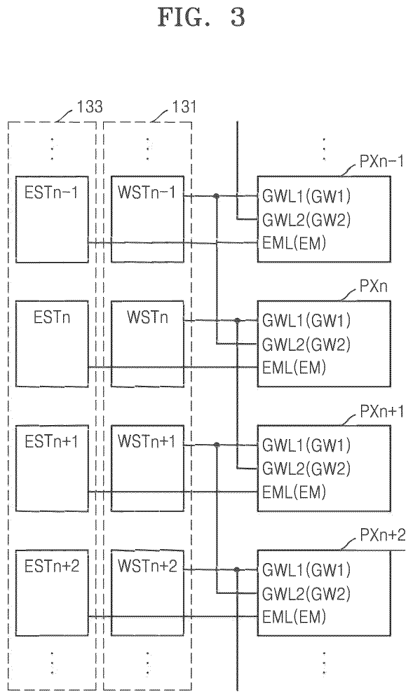

FIG. 2 is a schematic diagram of the display device 10 according to at least one example embodiment. FIG. 3 is a schematic diagram of a portion of a gate driving circuit of FIG. 2.

Referring to FIG. 2, the display device 10 may include a display panel 110. The display panel 110 may include a substrate, and in the display area DA of the substrate, a plurality of gate control lines GSL, a plurality of data lines DL, and a plurality of pixels PX connected thereto may be arranged. The plurality of pixels PX may be repeatedly arranged in a first direction (e.g., a row direction) and a second direction (e.g., a column direction). In at least one example embodiment, the first direction may be one of the x or y directions, and the second direction is the other of the x or y directions. Each pixel PX may include a display element (a light-emitting diode), and the display element may be connected to a pixel circuit. For example, in at least one example embodiment, each pixel PX may include an organic light-emitting diode as the display element, and the organic light-emitting diode may be connected to the pixel circuit. The pixel circuit may include a plurality of transistors and at least one capacitor. Each pixel PX may be connected to a corresponding gate control line from among the gate control lines GSL and a corresponding data line from among the data lines DL.

The gate control lines GSL may each extend in the first direction (row direction) and may be connected to the pixels PX located in the same row. The gate control lines GSL may be configured to respectively transmit gate control signals GSS to the pixels PX in the same row. For example, the gate control lines GSL may include first gate lines GWL1, second gate lines GWL2, and third gate lines EML, and the first gate lines GWL1, the second gate lines GWL2, and the third gate lines EML may be arranged in respective rows. The gate control signals GSS may include gate signals GW provided to the first gate lines GWL1 and the second gate lines GWL2, and a gate control signal (hereinafter, referred to as ‘emission control signal EM’) provided to the third gate lines EML. Hereinafter, the third gate line EML may be referred to as an emission control line EML, and the gate control signal provided to the third gate line EML may be referred to as the emission control signal EM.

The data lines DL may each extend in the second direction (column direction) and may be connected to the pixels PX in the same column. The data lines DL may be configured to respectively transmit data signals to the pixels PX in the same column in synchronization with the gate control signals (e.g., the gate signals GW).

In the peripheral area (non-display area) PA outside the display area DA of the display panel 110, various conductive lines configured to transmit electrical signals to the display area DA, outer driving circuits electrically connected to pixel circuits, and pads to which a printed circuit board or a driver Integrated Circuit (IC) chip is attached may be located. The outer driving circuits may include a gate driving circuit 130, a data driving circuit 150, a power supply circuit 170, and a controller 190.

In at least one example embodiment, the gate driving circuit 130, the data driving circuit 150, the power supply circuit 170, and the controller 190 may be mounted on the display panel 110 as driving chips. The data driving circuit 150, the power supply circuit 170, and the controller 190 may be formed as individual integrated circuit (IC) chips or a single IC chip and may be arranged on a Flexible Printed Circuit Board (FPCB) that is electrically connected to a pad arranged on one side of the substrate forming the display panel 110. In at least one example embodiment, the data driving circuit 150, the power supply circuit 170, and the controller 190 may be directly arranged on the substrate in a Chip On Glass (COG) manner or a Chip On Plastic (COP) manner.

In at least one example embodiment, some or all portions of the gate driving circuit 130 may be directly formed in the peripheral area of the substrate during a process of forming transistors configured to form a pixel circuit in the display area of the substrate. The gate driving circuit 130 may include an Amorphous Silicon thin-film transistor (TFT) Gate Driver Circuit (ASG), a Low Temperature Polycrystalline Silicon (LTPS) TFT Gate driver circuit, an Oxide Semiconductor TFT Gate driver circuit (OSG), and/or the like embedded in the display panel 110.

The gate driving circuit 130 may be connected to the gate control lines GSL, generate the gate control signal GSS according to a gate driving control signal GCS from the controller 190, and sequentially provide the gate control signal GSS to the gate control lines GSL. The gate control line GSL may be connected to a gate of a transistor included in the pixel PX, and the gate control signal GSS may be a gate control signal configured to control the turning on and off of the transistor connected to the gate control line GSL. The gate control signal GSS may include a gate-on voltage, at which a transistor may be turned on, and a gate-off voltage, at which a transistor may be turned off. In at least one example embodiment, the gate driving control signal GCS may include a start signal and a plurality of clock signals. In at least one example embodiment, the gate driving circuit 130 may be arranged on the left side and/or the right side of the display area DA.

The gate driving circuit 130 may include a first driving circuit 131 and a second driving circuit 133.

The first driving circuit 131 may be connected to a plurality of first gate lines GWL1 and a plurality of second gate lines GWL2. The first driving circuit 131 may sequentially output the gate signals GW according to a first control signal GCS1. As shown in FIG. 3, the first driving circuit 131 may include a plurality of stages . . . , WSTn−1, WSTn, WSTn+1, WSTn+2, . . . that are sequentially connected, and each of the stages . . . , WSTn−1, WSTn, WSTn+1, WSTn+2, ... may correspond to each row of the display panel 110. Each of the stages . . . , WSTn−1, WSTn, WSTn+1, WSTn+2, . . . may generate a gate signal GW. The gate signal GW may be output to a first gate line GWL1 in a corresponding row and a second gate line GWL2 in a next row. Four (4) stages of the first driving circuit 131 of FIG. 3 are illustrated for brevity, but the examples are not limited thereto. More specifically, the first driving circuit 131 may include more than the illustrated number of stages.

The gate signals GW output from the stages ..., WSTn−1, WSTn, WSTn+1, WSTn+2, . . . may be sequentially shifted. For example, the gate signals GW may be shifted at intervals of one first horizontal period H and sequentially output. The number of stages WST of the first driving circuit 131 may be the same as the number of rows.

In at least one example embodiment, a second gate line GWL2 in each row may be connected to a first gate line GWL1 in a previous row. The gate signal GW provided to the first gate line GWL1 is referred to as the first gate signal GW1, and the gate signal GW provided to the second gate line GWL2 is referred to as the second gate signal GW2. For example, a gate signal GW output from an n^{th} stage WSTn corresponding to an n^{th} row of the first driving circuit 131 may be the first gate signal GW1 provided to the first gate line GWL1 in the n^{th} row, and a second gate signal GW2 provided to a second gate line GWL2 in the (n+1)^{th} row. The second gate signal GW2 is the gate signal GW provided to the first gate line GWL1 in the previous row and thus may be referred to as the previous gate signal.

In at least one example embodiment, the previous gate signal that is input to the second gate line GWL2 in the first row may be the gate signal GW that is output from at least one dummy stage arranged before the first stage WST1.

The second driving circuit 133 may be connected to the emission control lines EML and may sequentially provide emission control signals EM to the emission control lines EML according to the second control signal GCS2. As shown in FIG. 3, the second driving circuit 133 may include a plurality of stages . . . , ESTn−1, ESTn, ESTn+1, ESTn+2, . . . that are sequentially connected, and each of the stages . . . , ESTn−1, ESTn, ESTn+1, ESTn+2, . . . may correspond to each row of the display panel 110. Each of the stages . . . , ESTn−1, ESTn, ESTn+1, ESTn+2, . . . may generate an emission control signal EM. Four (4) stages of the second driving circuit 132 of FIG. 3 are illustrated for brevity, but the examples are not limited thereto. More specifically, the second driving circuit 132 may include more than the illustrated number of stages.

The emission control signals EM that are respectively output from the stages . . . , ESTn−1, ESTn, ESTn+1, ESTn+2, . . . may be sequentially shifted. For example, the emission control signals EM may be shifted at intervals of one horizontal period H and sequentially output. The number of stages EST of the second driving circuit 133 may be the same as the number of rows.

The data driving circuit 150 may be connected to the data lines DL and configured to generate data signals DATA in response to data driving control signal DCS from the controller 190. The data signal DATA may be transmitted to the pixel circuits of the pixels PX through the data lines DL. The data signals DATA that are input to the data lines DL may be input to the pixels PX to which the gate signals GW are input. The data driving circuit 150 may convert grayscale input image data, which is received from the controller 190, into a data signal DATA in the form of voltage or current. In at least one example embodiment, the data driving control signal DCS may include a start signal and a plurality of clock signals.

The power supply circuit 170 may generate signals (voltages and currents) applied during the operation of the pixels PX in response to a power driving control signal PCS from the controller 190.

When the display device 10 is an organic light-emitting display device, the power supply circuit 170 may provide a first driving voltage ELVDD and a second driving voltage ELVSS. The first driving voltage ELVDD may be provided to the pixel circuits of the pixel PX through the driving voltage line arranged in the display area DA, and the second driving voltage ELVSS may be applied to an opposite electrode of the display element. The first driving voltage ELVDD may be a high-level voltage provided to a terminal of a driving transistor connected to a first electrode (a pixel electrode or an anode) of the organic light-emitting diode of each pixel PX. The second driving voltage ELVSS may be a low-level voltage provided to a second electrode (an opposite electrode or a cathode) of an organic light-emitting diode. The first driving voltage ELVDD and the second driving voltage ELVSS may be driving voltages for illuminating the pixels PX. The power supply circuit 170 may generate a reference voltage VREF, a first initialization voltage VINT, and a second initialization voltage VAINT and provide the same to the pixels PX.

The power supply circuit 170 may generate a high-level voltage VGH and a low-level voltage VGL and provide the same to the gate driving circuit 130.

The controller 190 may generate a gate driving control signal GCS, a data driving control signal DCS, and a power driving control signal PCS, based on signals that are input from the outside. The controller 190 may supply the gate driving control signal GCS to the gate driving circuit 130, the data driving control signal DCS to the data driving circuit 150, and the power driving control signal PCS to the power supply circuit 170.

In at least one example embodiment, the display device 10 may be connected to a processor of an electronic device. In at least one example embodiment, the processor may include an Application Processor (AP). The controller 190 may receive an on-operation signal, for example, a power-on signal and/or an operation flag signal, from the AP. When the electronic device is powered on or awake in a sleep mode by a user, the controller 190 may receive the on-operation signal from the AP, generate the gate driving control signal GCS, the data driving control signal DCS, and the power driving control signal PCS based on the on-operation signal, and output the same.

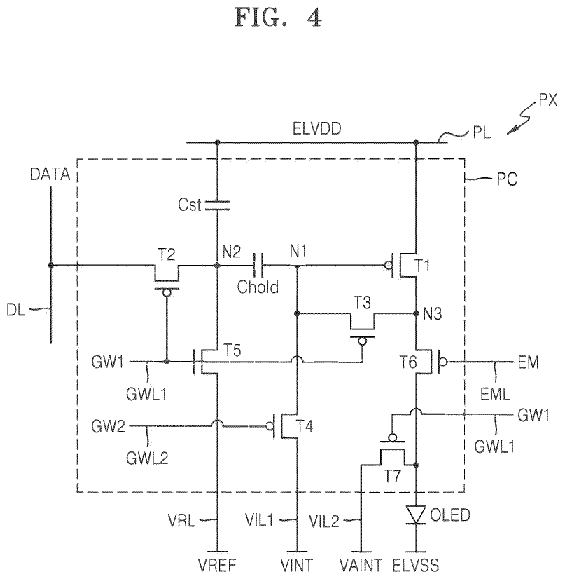

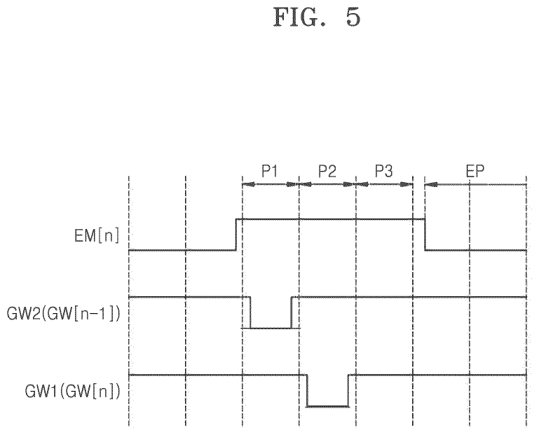

FIG. 4 is a schematic equivalent circuit diagram of a pixel according to at least one example embodiment. FIG. 5 is a timing diagram showing the operation of the pixel of FIG. 4, according to at least one example embodiment.

Referring to FIG. 4, a pixel PX may include a pixel circuit PC and an organic light-emitting diode OLED as a light-emitting diode connected to the pixel circuit PC.

The pixel circuit PC may include a first transistor T1 to a seventh transistor T7, a first capacitor Cst, and a second capacitor Chold. Signal lines connected to the pixel circuit PC may include a data line DL, a first gate line GWL1, a second gate line GWL2, an emission control line EML, a driving voltage line PL, a reference voltage line VRL, a first initialization voltage line VIL1, and a second initialization voltage line VIL2.

The first transistor T1 may be a driving transistor in which the intensity of a source-drain current is determined according to a gate-source voltage (or Vgs), and the second transistor T2 to the seventh transistor T7 may each be a switching transistor that is turned on/off according to a gate-source voltage, substantially, a gate voltage. In at least one example embodiment, the first transistor T1 to the seventh transistor T7 may be realized as thin-film transistors (TFT). Depending on the type (P-type or N-type) and/or the operation conditions of the transistor, a first terminal of each of the first transistor T1 to the seventh transistor T7 may be a source or a drain, and a second terminal thereof may be different from the first terminal. For example, when the first terminal is a source, the second terminal may be a drain.

In at least one example embodiment, the first transistor T1 to the seventh transistor T7 may have different channel types (conductivity types). Some of the first transistor T1 to the seventh transistor T7 may be N-channel transistors, while the others may be P-channel transistors. As shown in FIG. 4, for example, the fifth transistor T5 among the first transistor T1 to the seventh transistor T7 may an N-channel transistor, and the first transistor T1, the second transistor T2, the third transistor T3, the fourth transistor T4, the sixth transistor T6, and the seventh transistor T7 may each be a P-channel transistor.

The N-channel transistor may be an oxide thin-film transistor including an oxide semiconductor. A semiconductor of the oxide thin-film transistor may include an oxide, such as amorphous Indium gallium zinc-oxide (IGZO), zinc oxide (ZnO), titanium oxide (TiO), and/or the like. The gate-on voltage of a gate control signal configured to turn on an N-channel transistor may be a comparatively high-level voltage (first-level voltage), and the gate-off voltage of a gate control signal configured to turn off the N-channel transistor may be a comparatively low-level voltage (second-level voltage). For brevity, the first-level voltage and the second-level voltage may also be referred to as a high-level voltage and a low-level voltage, respectively.

The P-channel transistor may be a silicon thin-film transistor including a silicon semiconductor. For example, the semiconductor of the silicon thin-film transistor may include amorphous silicon, polysilicon, or the like. The gate-on voltage of a gate control signal configured to turn on a P-channel transistor may be a low-level voltage (second-level voltage), and the gate-off voltage of a gate control signal configured to turn off the P-channel transistor may be a high-level voltage (first-level voltage).

The first transistor T1 may be connected between the driving voltage line PL and the organic light-emitting diode OLED as a display element. The first transistor T1 may be connected to the driving voltage line PL and a third node N3. The first transistor T1 may be connected to the organic light-emitting diode OLED via the sixth transistor T6. The f irst transistor T1 may include a gate, a first terminal connected to the driving voltage line PL, and a second terminal. The first transistor T1 may be configured to output a driving current corresponding to the voltage applied to a first node N1 and provide the driving current to the organic light-emitting diode OLED. Hereinafter, the node connected to the gate of the first transistor T1 is referred to as the first node N1, and the node connected to the second terminal is referred to as the third node N3.

The second transistor T2 may be connected to the data line DL and a second node N2. The second transistor T2 may include a gate connected to the first gate line GWL1, a first terminal connected to the data line DL, and a second terminal connected to the second node N2. The second transistor T2 may be turned on in response to a first gate signal GW1 transmitted through the first gate line GWL1 and may be configured to transmit a data signal DATA, which is transmitted through the data line DL, to the second node N2.

The third transistor T3 may be connected to the gate and the second terminal of the first transistor T1. The third transistor T3 may include a gate connected to the first gate line GWL1, a first terminal connected to the first node N1, and a second terminal connected to the third node N3. When the third transistor T3 is turned on in response to the first gate signal GW1 transmitted through the first gate line GWL1, the first transistor T1 may be diode-connected. When the first transistor T1 is diode-connected, the threshold voltage of the first transistor T1 may be compensated.

The fourth transistor T4 may be connected to the gate of the first transistor T1 and the first initialization voltage line VIL1. The fourth transistor T4 may include a gate connected to the second gate line GWL2, a first terminal connected to the first node N1, and a second terminal connected to the first initialization voltage line VIL1. The fourth transistor T4 may be turned on in response to the second gate signal GW2 transmitted through the second gate line GWL2 and may be configured to transmit the first initialization voltage VINT to the first node N1, thus initializing the first node N1, that is, the gate of the first transistor T1.

The fifth transistor T5 may be connected to the second terminal of the second transistor T2 and a reference voltage line VRL. The fifth transistor T5 may include a gate connected to the first gate line GWL1, a first terminal connected to the second node N2, and a second terminal connected to the reference voltage line VRL. The fifth transistor T5 may be turned on in response to the first gate signal GW1 transmitted through the first gate line GWL1 and may transmit the reference voltage VREF to the second node N2.

The sixth transistor T6 may be connected to the first transistor T1 and the organic light-emitting diode OLED. The sixth transistor T6 may include a gate connected to the emission control line EML, a first terminal connected to the third node N3, and a second terminal connected to the organic light-emitting diode OLED. The second terminal of the sixth transistor T6 may be connected to the pixel electrode of the organic light-emitting diode OLED. When the sixth transistor T6 is turned on in response to the emission control signal EM transmitted through the emission control line EML, a driving current may flow through the organic light-emitting diode OLED.

The seventh transistor T7 may be connected to the organic light-emitting diode OLED and the second initialization voltage line VIL2. The seventh transistor T7 may include a gate connected to the first gate line GWL1, a first terminal connected to the pixel electrode, and a second terminal connected to the second initialization voltage line VL2. The seventh transistor T7 may be turned on in response to the first gate signal GW1 transmitted through the first gate line GWL1 and may be configured to transmit the second initialization voltage VAINT to the pixel electrode, thereby initializing the pixel electrode.

The first capacitor Cst may be connected to the driving voltage line PL and the second terminal of the second transistor T2. The first capacitor Cst may include a first electrode connected to the driving voltage line PL and a second electrode connected to the second node N2. The first capacitor Cst may store a voltage corresponding to the voltage difference between the driving voltage line PL and the second node N2.

The second capacitor Chold may be connected to the second terminal of the second transistor T2 and the gate of the first transistor T1. The second capacitor Chold may include a first electrode connected to the second node N2 and a second electrode connected to the first node N1. The second capacitor Chold may store a voltage corresponding to the voltage difference between the first node N1 and the second node N2.

The organic light-emitting diode OLED may include the pixel electrode (e.g., an anode) and an opposite electrode (e.g., a cathode) facing the pixel electrode, and the opposite electrode may receive the second driving voltage ELVSS. The organic light-emitting diode OLED may receive the driving current corresponding to the data signal DATA from the first transistor T1 and emit light. The emitted light may be of a certain color, thereby displaying a component of an image.

Hereinafter, the operation of the pixel PX is described with reference to FIG. 5.

FIG. 5 illustrates an n^{th} emission control signal EM[n] that is output from an n^{th} stage ESTn of the second driving circuit 133, an n^{th} gate signal GW[n] that is output from the n^{th} stage WSTn of the first driving circuit 131, and an (n−1)^{th} gate signal GW[n−1] that is output from the (n−1)^{th} stage WSTn−1. For convenience of explanation, the n^{th} gate signal GW[n] is referred to as the first gate signal GW1, and the (n−1)^{th} gate signal GW[n−1] is referred to as the second gate signal GW2. In at least one example embodiment, the second gate signal GW2 may have the same waveform as the first gate signal GW1 but shifted in time relative to the first gate signal GW1. For example, the second gate signal GW2 may be shifted forward in time relative to the first gate signal.

The power supply circuit 170 may be configured to provide the first driving voltage ELVDD to the driving voltage line PL, the second driving voltage ELVSS to the opposite electrode, the reference voltage VREF to the reference voltage line VRL, the first initialization voltage VINT to the first initialization voltage line VIL1, and the second initialization voltage VAINT to the second initialization voltage line VIL2.

Referring to FIG. 5, during a frame, the pixel PX may perform initialization, compensation, and data writing during the non-emission period and may emit light during the emission period. The period during which the emission control signal EM is at a gate-on voltage may be the emission period. The period during which the emission control signal EM is at a gate-off voltage may be the non-emission period. The non-emission period may include a first period P1, a second period P2, and a third period P3. The gate-on voltage of the emission control signal EM may be determined based on the channel type of the transistor to which the emission control signal EM is applied. Referring to FIG. 5, the gate-on voltage of the emission control signal EM may be the second-level voltage.

The first period P1 may be a gate node initialization period during which the first node N1 connected to the gate of the first transistor T1 is initialized. During the first period P1, the first gate signal GW1 having a first-level voltage may be provided to the first gate line GWL1, the second gate signal GW2 having a second-level voltage may be provided to the second gate line GWL2, and the emission control signal EM having a first-level voltage may be provided to the emission control line EML.

The fifth transistor T5 may be turned on in response to the first gate signal GW1 having the first-level voltage, while the second transistor T2, the third transistor T3, and the seventh transistor T7 may be turned off. The fourth transistor T4 may be turned on in response to the second gate signal GW2 having the second-level voltage. The sixth transistor T6 may be turned off in response to the emission control signal EM having the first-level voltage.

The reference voltage VREF may be transmitted to the second node N2 by the fifth transistor T5 that is on. The gate of the first transistor T1 may be initialized to the first initialization voltage VINT by the fourth transistor T4 that is on.

The second period P2 may be a compensation period during which the threshold voltage of the first transistor T1 is compensated. During the second period P2, the first gate signal GW1 having a second-level voltage may be provided to the first gate line GWL1, the second gate signal GW2 having a first-level voltage may be provided to the second gate line GWL2, and the emission control signal EM having a first-level voltage may be provided to the emission control line EML.

The fifth transistor T5 may be turned off in response to the first gate signal GW1 having the second-level voltage, while the second transistor T2, the third transistor T3, and the seventh transistor T7 may be turned on. The fourth transistor T4 may be turned off in response to the second gate signal GW2 having the first-level voltage. The sixth transistor T6 may be turned off in response to the emission control signal EM having the first-level voltage.

The voltage corresponding to the data signal DATA may be transmitted to the second node N2 by the second transistor T2 that is on. The first transistor T1 may be diode-connected through the third transistor T3 that is on, and may be turned on as the first driving voltage ELVDD is applied to the first terminal of the first transistor T1. When the gate-source voltage Vgs of the first transistor T1 reaches the threshold voltage Vth of the first transistor T1, the first transistor T1 may be turned off, and the voltage at the gate of the first transistor T1 may be (ELVDD−|Vth|).

The second initialization voltage VAINT may be applied to the pixel electrode of the organic light-emitting diode OLED through the seventh transistor T7 that is on, and thus, the pixel electrode may be initialized. Accordingly, the second period P2 may be an anode initialization period.

The third period P3 may be a writing period (data programming period) during which a data signal is applied to the pixel PX. During the third period P3, the first gate signal GW1 having a first-level voltage may be provided to the first gate line GWL1, the second gate signal GW2 having a first-level voltage may be provided to the second gate line GWL2, and the emission control signal EM having a first-level voltage may be provided to the emission control line EML.

The sixth transistor T6 may be turned off in response to the emission control signal EM having the first-level voltage. The second transistor T2, the third transistor T3, and the seventh transistor T7 may be turned off in response to the first gate signal GW1 having the first-level voltage, while the fifth transistor T5 may be turned on. The fourth transistor T4 may be turned off in response to the second gate signal GW2 having the first-level voltage.

The reference voltage VREF may be applied to the second node N2 through the fifth transistor T5 that is on, and the voltage at the second node N2 may change to the reference voltage VREF from the voltage Vdata corresponding to the data signal DATA. The voltage at the first node N1 may become (ELVDD−|Vth|+VREF−Vdata), which is a voltage changed according to the voltage variation (Vdata−VREF) at the second node N2. For example, the voltage at the first node N1 may be changed by an amount corresponding to the voltage variation (Vdata−VREF). The second capacitor Chold may be charged with the threshold voltage Vth of the first transistor T1 and the voltage Vdata corresponding to the data signal DATA.

The emission period EP may be a period during which the organic light-emitting diode OLED emits light. During the emission period EP, the first gate signal GW1 having a first-level voltage may be provided to the first gate line GWL1, the second gate signal GW2 having a first-level voltage may be provided to the second gate line GWL2, and the emission control signal EM having a second-level voltage may be provided to the emission control line EML.

The second transistor T2, the third transistor T3, and the seventh transistor T7 may be turned off in response to the first gate signal GW1 having the first-level voltage, while the fifth transistor T5 may be turned on. The fourth transistor T4 may be turned off in response to the second gate signal GW2 having the first-level voltage. The sixth transistor T6 may be turned on in response to the emission control signal EM having the second-level voltage, and the current path from the driving voltage line PL to the organic light-emitting diode OLED may be formed. The first transistor T1 may output a driving current (Id∝(Vdata−VREF)²), the magnitude of which corresponds to the difference (Vgs−Vth) between the gate-source voltage Vgs of the first transistor T1 and the threshold value Vth thereof. The driving current may flow to the organic light-emitting diode OLED through the sixth transistor T6 that is on, and the organic light-emitting diode OLED may emit light at brightness corresponding to the driving current. For example, the intensity of the emitted light may increase with an increase in the magnitude of the driving current.

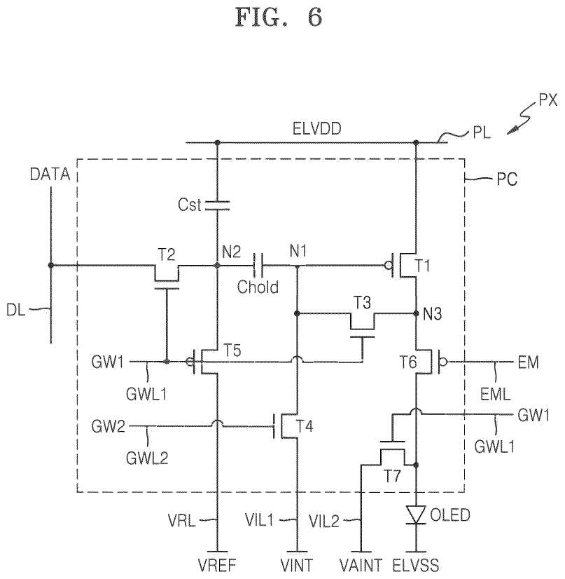

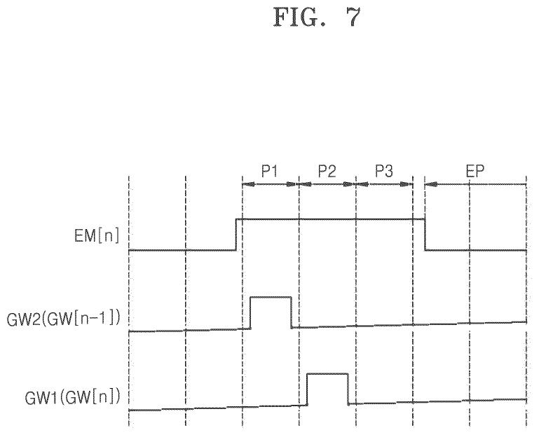

FIG. 6 is a schematic equivalent circuit diagram of a pixel according to at least one example embodiment. FIG. 7 is a timing diagram showing the operation of the pixel of FIG. 6.

A pixel PX of FIG. 6 is different from the pixel PX of FIG. 4 in that the first transistor T1, the fifth transistor T5, and the sixth transistor T6 are P-channel transistors, while the second transistor T2, the third transistor T3, the fourth transistor T4, and the seventh transistor T7 are N-channel transistors. Referring to FIG. 7, the voltage levels of the first gate signal GW1 and the second gate signal GW2 are opposite to those of the first gate signal GW1 and the second gate signal GW2 of FIG. 5.

During the first period P1, the first gate signal GW1 having a second-level voltage may be provided to the first gate line GWL1, the second gate signal GW2 having a first-level voltage may be provided to the second gate line GWL2, and the emission control signal EM having a first-level voltage may be provided to the emission control line EML.

During the second period P2, the first gate signal GW1 having a first-level voltage may be provided to the first gate line GWL1, the second gate signal GW2 having a second-level voltage may be provided to the second gate line GWL2, and the emission control signal EM having a first-level voltage may be provided to the emission control line EML.

During the third period P3, the first gate signal GW1 having a second-level voltage may be provided to the first gate line GWL1, the second gate signal GW2 having a second-level voltage may be provided to the second gate line GWL2, and the emission control signal EM having a first-level voltage may be provided to the emission control line EML.

During the emission period EP, the first gate signal GW1 having a second-level voltage may be provided to the first gate line GWL1, the second gate signal GW2 having a second-level voltage may be provided to the second gate line GWL2, and the emission control signal EM having a second-level voltage may be provided to the emission control line EML.

Otherwise, the operation of the pixel PX of FIG. 6, which is described with reference to FIG. 7, is the same as (and/or substantially similar to) that of the pixel PX of FIG. 4, which is described with reference to FIG. 5, and thus, the descriptions thereof are omitted.

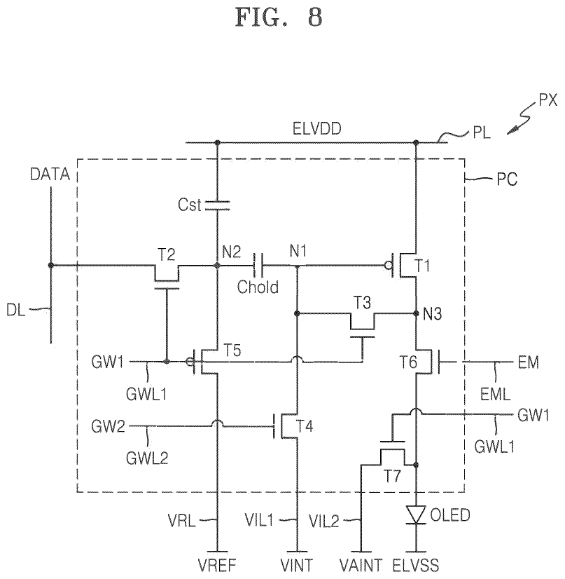

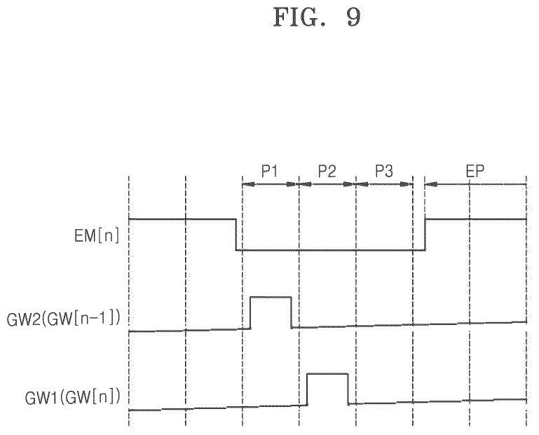

FIG. 8 is a schematic equivalent circuit diagram of a pixel according to at least one example embodiment. FIG. 9 is a timing diagram showing the operation of the pixel of FIG. 8.

A pixel PX of FIG. 8 is different from the pixel PX of FIG. 6 in that the sixth transistor T6 is an N-channel transistor. Referring to FIG. 9, the voltage level of the emission control signal EM may be opposite to that of the emission control signal EM of FIG. 7. The emission control signal EM having the second-level voltage may be provided during the first period P1, the second period P2, and the third period P3, and the emission control signal EM having the first-level voltage may be provided during the emission period EP. Referring to FIG. 9, the gate-on voltage of the emission control signal EM may be the first-level voltage.

Otherwise, the operation of the pixel PX of FIG. 8, which is described with reference to FIG. 9, is the same as (and/or substantially similar to) that of the pixel PX of FIG. 4, which is described with reference to FIG. 5; thus, the descriptions thereof are omitted.

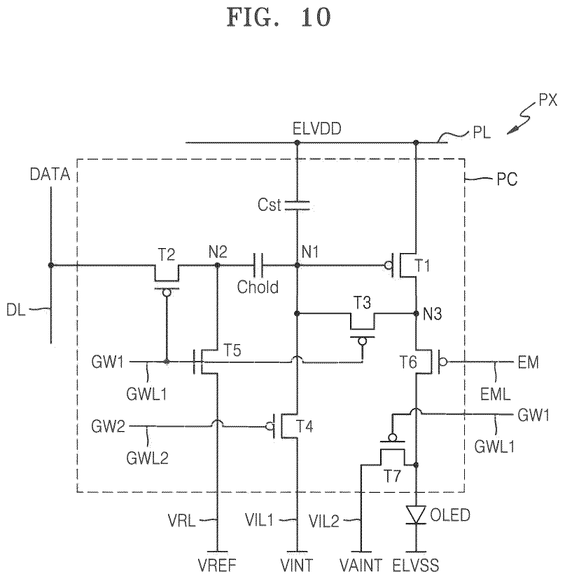

FIGS. 10 to 12 respectively are schematic equivalent circuit diagrams of a pixel according to at least one example embodiment.

A pixel PX of FIG. 10 is different from the pixel PX of FIG. 4 in that the first capacitor Cst is connected to the driving voltage line PL and the gate of the first transistor T1.

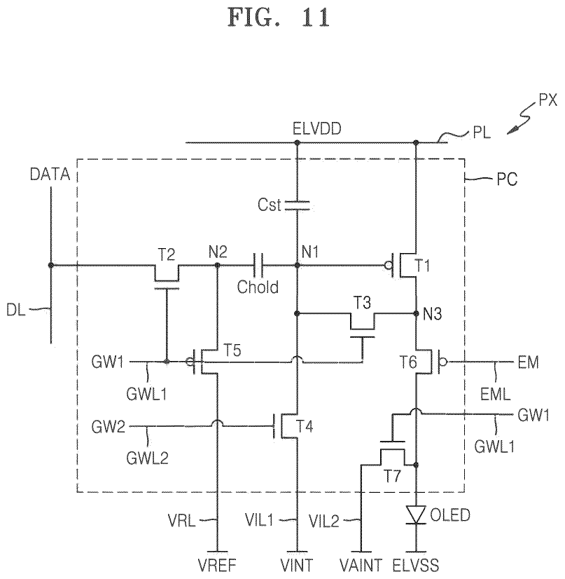

A pixel PX of FIG. 11 is different from the pixel PX of FIG. 6 in that the first capacitor Cst is connected to the driving voltage line PL and the gate of the first transistor T1.

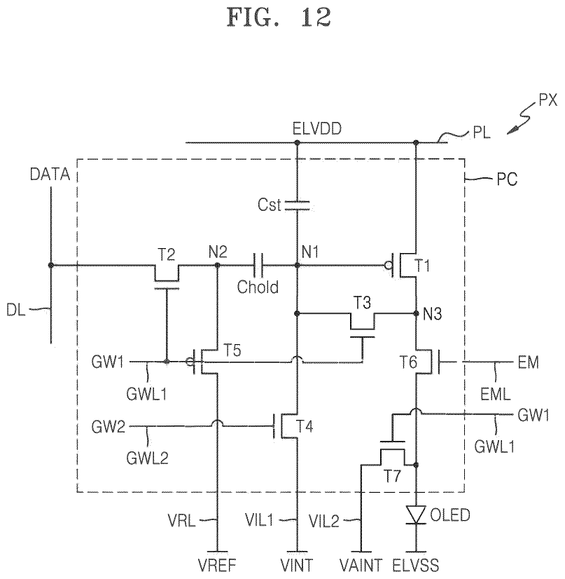

A pixel PX of FIG. 12 is different from the pixel PX of FIG. 8 in that the first capacitor Cst is connected to the driving voltage line PL and the gate of the first transistor T1.

Referring to FIGS. 10 to 12, the first capacitor Cst may include a first electrode connected to the driving voltage line PL and a second electrode connected to the first node N1. The first capacitor Cst may store a voltage corresponding to the voltage difference between the driving voltage line PL and the first node N1.

The operation of the pixel PX of FIGS. 10 to 12 is the same as (and/or substantially to) that of the operation of the pixel PX of FIG. 4, which is described with reference to FIG. 5, and thus, the descriptions thereof are omitted.

The pixel PX according to one or more embodiments includes a plurality of transistors, but as the turning on and off of the transistors is controlled by two gate control signals, the size of the driving circuit may be reduced, leading to a reduction in the size (area) of the non-display area.

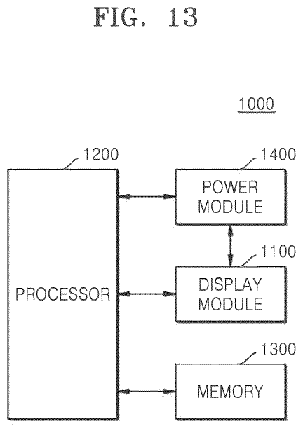

FIG. 13 is a block diagram of an electronic device according to at least one example embodiment.

Referring to FIG. 13, an electronic device 1000 according to at least one example embodiment may include a display module 1100, a processor 1200, a memory 1300, a power module 1400.

The electronic device 1000 may use the display module 1100 to output various types of information under the operating system.

The processor 1200 may include at least one of a Central Processing Unit (CPU), an AP, a Graphics Processing Unit (GPU), a Communication Processor (CP), an Image Signal Processor (ISP), and a controller. In at least one example embodiment, the processor 1200 may be divided into at least two processors from a functional or structural perspective. For example, the processor 1200 may include a main processor in the form of a first driving chip, which includes a CPU, and an auxiliary processor in the form of a second driving chip, which includes a controller that receives an image signal from the main processor and processes the same to conform to the interface specifications of the display module 1100.

The memory 1300 may include at least one of non-volatile memory and/or volatile memory. In the memory 1300, data information required for the operation of the processor 1200 or the display module 1100 may be stored. When the processor 1200 executes an application stored in the memory 1300, an image data signal and/or an input control signal may be transmitted to the display module 1100, and the display module 1100 may process such signals to output image information through a display screen.

The power module 1400 may include a power supply module, such as a power adaptor or a battery device, and a power conversion module that generates power required for the operation of the electronic device 1000 by converting the power supplied by the power supply module. The power conversion by the power conversion module may include DC-DC conversion, AC-DC conversion, and DC-AC conversion, but is not limited thereto.

At least one of the components of the electronic device 1000 described above may be included in and/or connected to the display device according to the one or more embodiments. In addition, some of individual modules functionally included in a single module may be included in the display device, and others thereof may be provided separately from the display device. For example, the display device may include the display module 1100 and the auxiliary processor of the processor 1200, and the main processor of the processor 1200, the memory 1300, and the power module 1400 may be provided as separate devices in the electronic device 1000, rather than in the display device. As another example, the power module 1400 may be included in the display device and supply power to the processor 1200 and the memory 1300 provided in the electronic device 1000, rather than in the display device, and one or more embodiments are not limited thereto.

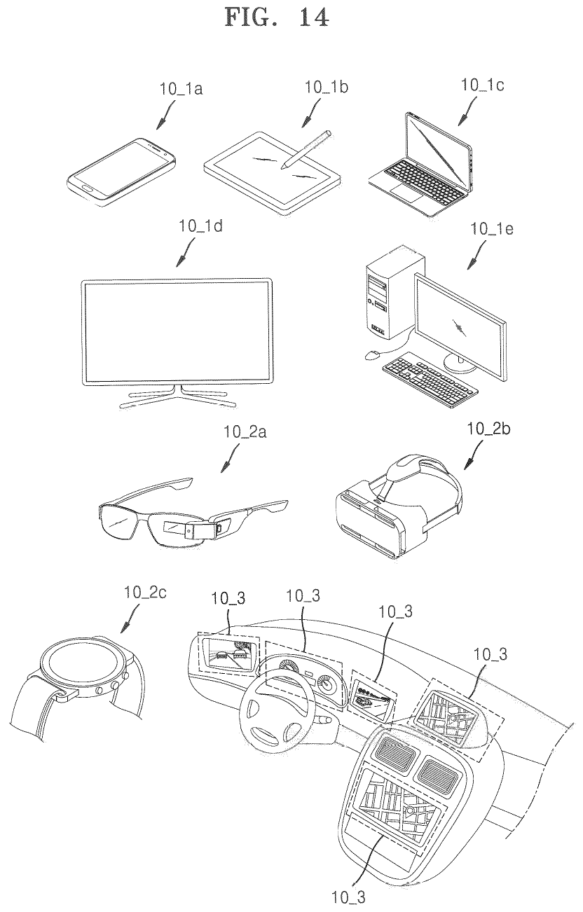

FIG. 14 is a schematic diagram of electronic devices according to one or more embodiments.

The display device according to one or more embodiments is a device that displays a moving image or a still image and is applicable to various electronic devices. Referring to FIG. 14, examples of various electronic devices to which the display device according to embodiments is applied may include: electronic devices for image display (such as a smartphone 10_1a, a tablet personal computer (PC) 10_1b, a laptop 10_1c, a television (TV) 10_1d, a desktop monitor 10_1e, and/or the like); wearable electronic devices including display modules (such as smart glasses 10_2a, a head-mounted display 10_2b, a smart watch 10_2c, and/or the like); vehicle electronic devices 10_3 with display modules (such as an instrument cluster of a vehicle, center fascia, a Center Information Display (CID) on the dashboard, a room mirror display, and/or the like); and/or the like. The electronic device 1000 according to embodiments is not limited to the devices stated above.

The electronic device of FIG. 14 may include the components shown in FIG. 13. For example, the smartphone 10_1a may include the display module 1100, the processor 1200, the memory 1300, and the power module 1400 shown in FIG. 13. The smartphone 10_1a may further include a communication module and a battery device. The power supplied by the battery device may be converted through the power module 1400 and provided to the processor 1200, the memory 1300, and the display module 1100. In at least one example embodiment, the display device applied to the smartphone 10_1a may include the display module 1100 and further include the power module 1400. The processor 1200 and the memory 1300 may be provided in the form of chips mounted on a motherboard that is an external device, but one or more embodiments are not limited thereto.

According to the one or more embodiments, a high-resolution display device with a reduced non-display area may be provided. However, the scope of the disclosure is not limited by the effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A pixel comprising:
a first transistor comprising a first terminal connected to a first voltage line;
a second transistor comprising a first terminal connected to a data line;
a third transistor connected to a gate and a second terminal of the first transistor;
a fourth transistor connected to the gate of the first transistor and a second voltage line;
a fifth transistor connected to a second terminal of the second transistor and a third voltage line;
a sixth transistor connected to the second terminal of the first transistor and a light-emitting diode;
a seventh transistor connected to the light-emitting diode and a fourth voltage line;
a first capacitor connected to the first voltage line and the second transistor; and
a second capacitor connected to the second terminal of the second transistor and the gate of the first transistor,
wherein a gate of the second transistor, a gate of the third transistor, a gate of the fifth transistor, and a gate of the seventh transistor are connected to a first gate line,
each of the second transistor, the third transistor, and the seventh transistor have a same channel type as the first transistor, and
a channel type of the fifth transistor is opposite to the channel type of the first transistor.

2. The pixel of claim 1, wherein a gate of the fourth transistor is connected to a second gate line,
the first gate line is configured to receive a first gate signal,
the second gate line is configured to receive a second gate signal, and
the second gate signal provided to the second gate line has a same waveform as the first gate signal provided to the first gate line and is shifted forward in time relative to the first gate signal.

3. The pixel of claim 2, wherein channel types of the fourth transistor and the sixth transistor are the same as the channel type of the first transistor.

4. The pixel of claim 3, wherein the pixel is configured such that
the second transistor is turned off by a first-level voltage of the first gate signal and turned on by a second-level voltage of the first gate signal,
the fifth transistor is turned on by the first-level voltage of the first gate signal and turned off by the second-level voltage of the first gate signal,
the fourth transistor is turned off by a first-level voltage of the second gate signal and turned on by a second-level voltage of the second gate signal,
the sixth transistor is turned off by a first-level voltage of a third gate signal and turned on by a second level of the third gate signal, the third gate signal provided to a gate of the sixth transistor, and
such that during a first period of a frame a voltage at the second terminal of the second transistor is a reference voltage provided to the third voltage line, and a voltage at the gate of the first transistor is a first initialization voltage provided to the second voltage line, and
wherein, during the first period of the frame, the second transistor is off, the fifth transistor is on, the fourth transistor is on, and the sixth transistor is off.

5. The pixel of claim 4, wherein, the pixel is configured such that, during a second period after the first period of the frame, the voltage at the second terminal of the second transistor corresponds to a data signal provided to the data line, and the voltage at the gate of the first transistor corresponds to a difference between a driving voltage provided to the first voltage line and a threshold voltage of the first transistor, and
wherein, during the second period, the second transistor is on, the fifth transistor is off, the fourth transistor is off, and the sixth transistor is off.

6. The pixel of claim 5, wherein the pixel is configured such that, during a third period after the second period of the frame, the voltage at the second terminal of the second transistor is the reference voltage, and the voltage at the gate of the first transistor is changed by an amount corresponding to a voltage variation at the second terminal of the second transistor,
wherein, during the third period, the second transistor is off, the fifth transistor is on, the fourth transistor is off, and the sixth transistor is off.

7. The pixel of claim 6, wherein the pixel is configured such that, during an emission period after the third period of the frame, the second transistor is off, the fifth transistor is on, the fourth transistor is off, and the sixth transistor is on.

8. A pixel comprising:
a first transistor comprising a first terminal connected to a first voltage line;
a second transistor comprising a first terminal connected to a data line;
a third transistor connected to a gate and a second terminal of the first transistor;
a fourth transistor connected to the gate of the first transistor and a second voltage line;
a fifth transistor connected to a second terminal of the second transistor and a third voltage line;
a sixth transistor connected to the second terminal of the first transistor and a light-emitting diode;
a seventh transistor connected to the light-emitting diode and a fourth voltage line;
a first capacitor connected to the first voltage line and the second transistor; and
a second capacitor connected to the second terminal of the second transistor and the gate of the first transistor,
wherein a gate of the second transistor, a gate of the third transistor, a gate of the fifth transistor, and a gate of the seventh transistor are connected to a first gate line,
channel types of the second transistor, the third transistor, and the seventh transistor are opposite to a channel type of the first transistor, and
the fifth transistor has a same channel type as the first transistor.

9. The pixel of claim 8, wherein a gate of the fourth transistor is connected to a second gate line,
the first gate line is configured to receive a first gate signal,
the second gate line is configured to receive a second gate signal, and
the second gate signal provided to the second gate line has a same waveform as the first gate signal provided to the first gate line and is shifted forward in time relative to the first gate signal.

10. The pixel of claim 9, wherein a channel type of the fourth transistor is opposite to the channel type of the first transistor, and
a channel type of the sixth transistor is the same as the channel type of the first transistor.

11. The pixel of claim 10, wherein the pixel is configured such that
the fourth transistor is turned on by a first-level voltage of the second gate signal and turned off by a second-level voltage of the second gate signal,
the second transistor is turned on by a first-level voltage of the first gate signal and turned off by a second-level voltage of the first gate signal,
the fifth transistor is turned off by the first-level voltage of the first gate signal and turned on by the second-level voltage of the first gate signal,
the sixth transistor is turned off by a first-level voltage of a third gate signal and turned on by a second-level voltage of the third gate signal, and
such that, during a first period of a frame, a voltage at the second terminal of the second transistor is a reference voltage provided to the third voltage line, and a voltage at the gate of the first transistor is a first initialization voltage provided to the second voltage line,
wherein, during first period of the frame, the fourth transistor is on, the second transistor is off, the fifth transistor is on, and the sixth transistor is off.

12. The pixel of claim 11, wherein the pixel is configured such that, during a second period after the first period of the frame,
the voltage at the second terminal of the second transistor corresponds to a data signal provided to the data line, and the voltage at the gate of the first transistor corresponds to a difference between a driving voltage provided to the first voltage line and a threshold voltage of the first transistor,
wherein, during the second period, the second transistor is on, the fifth transistor is off, the fourth transistor is off, and the sixth transistor is off.

13. The pixel of claim 12, wherein the pixel is configured such that, during a third period after the second period of the frame,
the voltage at the second terminal of the second transistor is the reference voltage, and the voltage at the gate of the first transistor is changed from a voltage in the second period by an amount corresponding to a voltage variation at the second terminal of the second transistor,
wherein, during the third period, the second transistor is off, the fifth transistor is on, the fourth transistor is off, and the sixth transistor is off.

14. The pixel of claim 13, wherein the pixel is configured such that, during an emission period after the third period of the frame, the second transistor is off and the fifth transistor is on, the fourth transistor is off, and the sixth transistor is on.

15. The pixel of claim 9, wherein channel types of the fourth transistor and the sixth transistor are opposite to the channel type of the first transistor.

16. The pixel of claim 15, wherein the pixel is configured such that
the fourth transistor is turned on by a first-level voltage of the second gate signal and turned off by a second-level voltage of the second gate signal,
the second transistor is turned on by a first-level voltage of the first gate signal and turned off by a second-level voltage of the first gate signal,
the fifth transistor is turned off by the first-level voltage of the first gate signal and turned on by the second-level voltage of the first gate signal,
the sixth transistor is turned on by a first-level voltage of a third gate signal and turned off by a second-level voltage of the third gate signal, and
such that, during a first period of a frame, a voltage at the second terminal of the second transistor is a reference voltage provided to the third voltage line, and a voltage at the gate of the first transistor is a first initialization voltage provided to the second voltage line,
wherein, during the first period of the frame, the fourth transistor is turned on, the second transistor is off, the fifth transistor is on, and the sixth transistor is off.

17. The pixel of claim 16, wherein the pixel is configured such that, during a second period after the first period of the frame, the voltage at the second terminal of the second transistor corresponds to a data signal provided to the data line, and the voltage at the gate of the first transistor corresponds to a difference between a driving voltage provided to the first voltage line and a threshold voltage of the first transistor,
wherein, during the second period, the second transistor is on, the fifth transistor is off, the fourth transistor is off, and the sixth transistor is off.

18. The pixel of claim 17, wherein the pixel is configured such that, during a third period after the second period of the frame, the voltage at the second terminal of the second transistor is the reference voltage, and the voltage at the gate of the first transistor is changed from a voltage in the second period by an amount corresponding to a voltage variation at the second terminal of the second transistor,
wherein, during the third period, the second transistor is off, the fifth transistor is on, the fourth transistor is off, and the sixth transistor is off.

19. The pixel of claim 18, wherein the pixel is configured such that, during an emission period after the third period of the frame, the second transistor is off and the fifth transistor is on, the fourth transistor is off, and the sixth transistor is on.

20. An electronic device comprising:
a controller configured to receive an on-operation signal from a processor and output a control signal based on the on-operation signal;
a gate driving circuit configured to receive the control signal and sequentially output at least one gate signal; and
a display panel in which a plurality of pixels are arranged, the plurality of pixels configured to receive the at least one gate signal,
wherein each of the plurality of pixels comprises
a first transistor comprising a first terminal connected to a first voltage line;
a second transistor comprising a first terminal connected to a data line;
a third transistor connected to a gate and a second terminal of the first transistor;
a fourth transistor connected to the gate of the first transistor and a second voltage line;
a fifth transistor connected to a second terminal of the second transistor and a third voltage line;
a sixth transistor connected to the second terminal of the first transistor and a light-emitting diode;
a seventh transistor connected to the light-emitting diode and a fourth voltage line;
a first capacitor connected to the first voltage line and the second transistor; and
a second capacitor connected to the second terminal of the second transistor and the gate of the first transistor,
wherein a gate of the second transistor, a gate of the third transistor, a gate of the fifth transistor, and a gate of the seventh transistor are connected to a first gate line,
the fifth transistor has a same or opposite channel type to the first transistor, and
a channel type of the fifth transistor is opposite to channel types of the second transistor and the third transistor.
